(19) United States
(12) Patent Application Publication
(10) Pub. No.: US 2026/0027817 A1
(43) Pub. Date: Jan. 29, 2026

(54) SEPARATION METHOD FOR OBJECT, TREATMENT METHOD FOR OBJECT, AND TREATMENT APPARATUS

(71) Applicant: DISCO CORPORATION, Tokyo (JP)

(72) Inventors: Kazuki Mori, Tokyo (JP); Jiro Genozono, Tokyo (JP)

(21) Appl. No.: 19/251,233

(22) Filed: Jun. 26, 2025

(30) Foreign Application Priority Data
Jul. 25, 2024 (JP) 2024-119213

(51) Int. Cl. B32B 43/00; H01L 21/67

(52) U.S. Cl. CPC B32B 43/006; H01L 21/67023; H01L 21/67051; B32B 2457/14

(57) ABSTRACT

There is provided a separation method for an object by which the object held by a holding surface is separated from the holding surface. The separation method includes ejecting a liquid from the holding surface in a state in which the object is held by the holding surface, separating the holding surface and the object while keeping a state in which the liquid is in contact with both the holding surface and the object by causing the holding surface and the object to relatively move in such a direction as to separate from each other after the ejecting the liquid from the holding surface, and removing the liquid in contact with both the holding surface and the object after the separating the holding surface and the object.

### BACKGROUND OF THE INVENTION

### Field of the Invention

The present invention relates to a separation method for an object by which the object held by a holding surface is separated from the holding surface, a treatment method for an object by which the object is treated, and a treatment apparatus that treats an object.

### Description of the Related Art

In a manufacturing process for device chips, a wafer in which a device is formed in each of a plurality of regions marked out by a plurality of streets (planned dividing lines) arranged in a lattice manner is used. The device chips including the device are manufactured by dividing this wafer along the streets to dice the wafer into individual pieces. The device chips are incorporated in various pieces of electronic equipment, such as mobile phones and personal computers.

In dividing the wafer, the wafer is treated by various treatment apparatuses. For example, the wafer is divided by a cutting apparatus that cuts an object by an annular cutting blade, a laser processing apparatus that executes laser processing for an object, or the like. Further, thin device chips are obtained by executing thinning treatment for the wafer before the dividing. For example, the wafer is thinned by a grinding apparatus that grinds an object, a polishing apparatus that polishes an object, or the like.

The wafer used for the manufacturing of the device chips is formed by slicing an ingot. For example, a splitting layer is formed inside the ingot by executing laser processing for the ingot by using a laser processing apparatus. A region in which the splitting layer has been formed in the ingot becomes more fragile than the other region. Thus, when an external force is given to the ingot in which the splitting layer has been formed, the ingot breaks, with the splitting layer being origin, and the wafer is split off from the ingot (refer to Japanese Patent Laid-open No. 2016-111143). Then, grinding processing or the like is executed for the ingot from which the wafer has been split off, and thereafter the ingot is reused for manufacturing of the next wafer.

When the object such as the wafer or the ingot is treated by a treatment apparatus in the above-described manner, the object is held by a holding unit included in the treatment apparatus. For example, the holding unit includes a holding surface connected to a suction source, and sucks and holds the object by the holding surface. However, when the object is sucked and held by the holding surface of the holding unit, it becomes difficult for the object after the treatment to separate from the holding surface, and smooth conveyance of the object is hindered. Thus, in conveying the object from the holding unit, a method in which removal of the object is assisted by ejecting a liquid such as water from the holding surface is sometimes used (refer to Japanese Patent Laid-open No. 2020-93330).

### SUMMARY OF THE INVENTION

As described above, detachment of an object from a holding surface is promoted by ejecting a liquid from the holding surface after the object is treated by a treatment apparatus. However, if the liquid ejected from the holding surface remains between the object and the holding surface, surface tension of the liquid acts on the holding surface and the object, and the object is attracted by the holding surface through the liquid. As a result, although the liquid is supplied for promoting the detachment of the object from the holding surface, an inconvenience that it becomes difficult for the object to separate from the holding surface due to the liquid occurs.

To detach the object in the state in which the surface tension of the liquid acts on the object from the holding surface, the object is required to be carefully lifted up by a strong force and be pulled away from the holding surface. Due to this, it becomes difficult to smoothly convey the object from the holding unit. Moreover, when the strong external force is given to the object, there is a possibility that deformation or damage of the object occurs and proper conveyance of the object is hindered.

The present invention has been made in view of such a problem, and an object thereof is to provide a separation method for an object, a treatment method for an object, and a treatment apparatus that can easily and properly separate the object from a holding surface.

In accordance with an aspect of the present invention, there is provided a separation method for an object by which the object held by a holding surface is separated from the holding surface. The separation method includes ejecting a liquid from the holding surface in a state in which the object is held by the holding surface, separating the holding surface and the object while keeping a state in which the liquid is in contact with both the holding surface and the object by causing the holding surface and the object to relatively move in such a direction as to separate from each other after the ejecting the liquid from the holding surface, and removing the liquid in contact with both the holding surface and the object after the separating the holding surface and the object.

Preferably, in the removing the liquid, the liquid in contact with both the holding surface and the object is removed by sucking the liquid by the holding surface. Further, preferably, the object is cleaned by the liquid ejected from the holding surface in the ejecting the liquid from the holding surface or in the separating the holding surface and the object. Moreover, preferably, the separation method for an object further includes cleaning the object by the liquid ejected from the holding surface in a state in which the relative movement between the holding surface and the object is stopped after the separating the holding surface and the object and before the removing the liquid in contact with both the holding surface and the object.

In accordance with another aspect of the present invention, there is provided a treatment method for an object by which the object is treated. The treatment method includes holding the object by a holding surface, treating the object held by the holding surface after the holding the object by the holding surface, and ejecting a liquid from the holding surface in a state in which the object is held by the holding surface after the treating the object. The treatment method also includes separating the holding surface and the object while keeping a state in which the liquid is in contact with both the holding surface and the object by causing the holding surface and the object to relatively move in such a direction as to separate from each other after the ejecting the liquid from the holding surface, and removing the liquid in contact with both the holding surface and the object after the separating the holding surface and the object.

In accordance with a further aspect of the present invention, there is provided a treatment apparatus including a holding unit having a holding surface that holds an object, a treatment unit that executes treatment for the object held by the holding surface, a liquid supply source that supplies the holding unit with a liquid to be ejected from the holding surface, a removal unit that removes the liquid ejected from the holding surface, and a controller. The controller is capable of causing the removal unit to remove the liquid in contact with both the holding surface and the object.

In the separation method for an object, the treatment method for an object, and the treatment apparatus according to the aspects of the present invention, the liquid in contact with both the holding surface and the object is removed in the separation of the object from the holding surface. This makes it possible to vanish the surface tension of the liquid acting on the object and easily and properly separate the object from the holding surface.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a block diagram depicting a treatment system;

FIG. 2 is a perspective view depicting a laser processing apparatus;

FIG. 3A is a front view depicting a splitting apparatus that holds an object;

FIG. 3B is a front view depicting the splitting apparatus that splits off a substrate from the object;

FIG. 4 is a perspective view depicting a grinding apparatus;

FIG. 5 is a flowchart depicting a treatment method for an object;

FIG. 6 is a sectional view depicting a treatment apparatus in a holding step;

FIG. 7 is a partially sectional front view depicting the treatment apparatus in a treatment step;

FIG. 8 is a partially sectional front view depicting the treatment apparatus in a liquid ejection step;

FIG. 9 is a partially sectional front view depicting the treatment apparatus in a movement step;

FIG. 10 is a partially sectional front view depicting the treatment apparatus in a cleaning step;

FIG. 11 is a partially sectional front view depicting the treatment apparatus in a liquid removal step;

FIG. 12 is a partially sectional front view depicting the treatment apparatus in a conveying step; and

FIG. 13 is a sectional view depicting the treatment apparatus in a foreign matter removal step.

### DETAILED DESCRIPTION OF THE PREFERRED EMBODIMENT

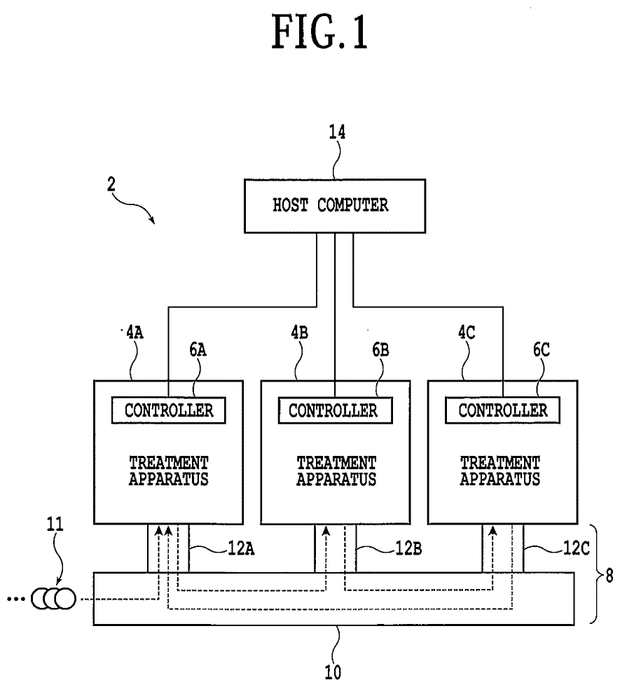

An embodiment according to an aspect of the present invention is described below with reference to the accompanying drawings. First, a description is given of a configuration example of a treatment system including a treatment apparatus that can execute a separation method for an object and a treatment method for an object according to the present embodiment. FIG. 1 is a block diagram depicting a treatment system 2.

The treatment system 2 is a system that can continuously execute a plurality of treatments for an object 11. The object 11 is an object (treatment-target object, workpiece) of the treatment by the treatment system 2. In the present embodiment, a description is given of a case in which the object 11 is an ingot used for manufacturing of a substrate (wafer). The substrate with a predetermined thickness is obtained by splitting off part of the ingot from the main body of the ingot. For example, the object 11 is a single-crystal ingot that is composed of a semiconductor material and has a column shape or a circular disc shape. In this case, a semiconductor wafer is obtained by splitting off the substrate from the object 11.

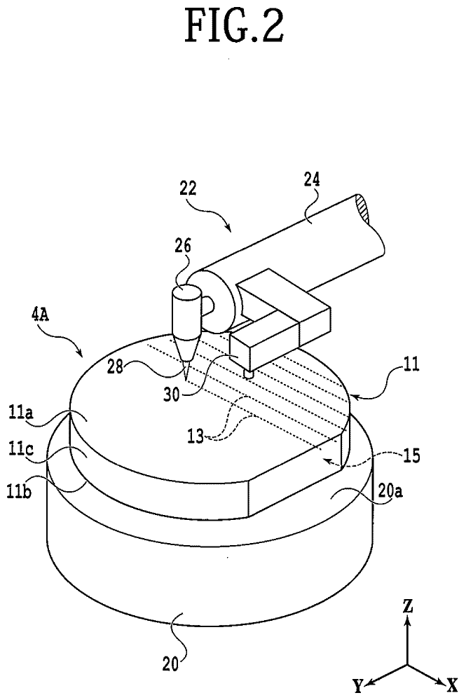

The treatment system 2 includes a plurality of treatment apparatuses 4A, 4B, and 4C that execute a predetermined treatment for the object 11. Specifically, the treatment apparatus 4A is a processing apparatus (laser processing apparatus) that executes laser processing for the object 11. The treatment apparatus 4B is a processing apparatus (splitting apparatus) that splits off a substrate from the object 11. The treatment apparatus 4C is a processing apparatus (grinding apparatus) that grinds the object 11 after splitting-off of the substrate. The substrate is manufactured from the object 11 through processing for the object 11 in the treatment apparatuses 4A, 4B, and 4C in turn. Specific configurations, functions, operation, and the like of the treatment apparatuses 4A, 4B, and 4C are described later (see FIGS. 2 to 4).

The treatment apparatuses 4A, 4B, and 4C include controllers (control units, control parts, control apparatuses) 6A, 6B, and 6C, respectively, that control the treatment apparatuses 4A, 4B, and 4C. The controller 6A is connected to constituent elements configuring the treatment apparatus 4A, and generates a control signal that controls operation of each constituent element of the treatment apparatus 4A. The controller 6B is connected to constituent elements configuring the treatment apparatus 4B, and generates a control signal that controls operation of each constituent element of the treatment apparatus 4B. The controller 6C is connected to constituent elements configuring the treatment apparatus 4C, and generates a control signal that controls operation of each constituent element of the treatment apparatus 4C.

For example, the controllers 6A, 6B, and 6C are configured by a computer, and include a processing section that executes processing of computation and the like required for operation of the treatment apparatus 4A, 4B, or 4C and a storage section that stores various kinds of information (data, program, and the like) used for the operation of the treatment apparatus 4A, 4B, or 4C. The processing section includes a processor such as a central processing unit (CPU). The storage section includes a memory such as a read only memory (ROM) and a random access memory (RAM).

Further, the treatment system 2 includes a conveying system 8 that conveys the object 11. The conveying system 8 includes a conveying unit (conveying mechanism) 10 that conveys the object 11 to the vicinity of the treatment apparatus 4A, 4B, or 4C and a plurality of conveying units (conveying mechanisms) 12A, 12B, and 12C that convey the object 11 between the treatment apparatus 4A, 4B, or 4C and the conveying unit 10. The conveying system 8 conveys the object 11 in a circulating manner such that a series of steps to treat the object 11 by the treatment apparatuses 4A, 4B, and 4C in turn is repeated.

The conveying unit 10 is formed of a belt conveyor or the like and, for example, conveys the object 11 to the vicinity of a conveying port (not depicted) of the treatment apparatus 4A, 4B, or 4C. The conveying units 12A, 12B, and 12C are formed of, for example, a conveying robot such as an articulated robot, and transfer the object 11 between the treatment apparatus 4A, 4B, or 4C and the conveying unit 10. Specifically, the conveying unit 12A conveys the object 11 between the conveying unit 10 and the treatment apparatus 4A. The conveying unit 12B conveys the object 11 between the conveying unit 10 and the treatment apparatus 4B. The conveying unit 12C conveys the object 11 between the conveying unit 10 and the treatment apparatus 4C.

Moreover, the treatment system 2 includes a host computer 14 that executes overall control of the treatment apparatuses 4A, 4B, and 4C and the conveying system 8. The host computer 14 is connected to constituent elements of the treatment system 2 (treatment apparatuses 4A, 4B, and 4C, conveying unit 10, and conveying units 12A, 12B, and 12C).

The treatment system 2 operates through transmission and reception of a signal between the host computer 14 and each constituent element. For example, the host computer 14 controls treatments for the object 11 by the treatment apparatuses 4A, 4B, and 4C by outputting a control signal to the controllers 6A, 6B, and 6C. Further, the host computer 14 controls conveyance of the object 11 by the conveying system 8 by outputting the control signal to the conveying unit 10 and the conveying units 12A, 12B, and 12C.

The host computer 14 includes a processing section that executes processing of computation and the like required for the operation of the treatment system 2 and a storage section that stores various kinds of information (data, program, and the like) used for the operation of the treatment system 2. The processing section includes a processor such as a CPU. The storage section includes a memory such as a ROM and a RAM.

When the treatment system 2 operates, first, the object 11 is conveyed to a front of the treatment apparatus 4A by the conveying unit 10. Then, the object 11 is carried in to the treatment apparatus 4A from the conveying unit 10 by the conveying unit 12A, and is treated by the treatment apparatus 4A. The treatment apparatus 4A executes laser processing for the object 11 as described later to form a splitting layer that functions as origin of splitting in the object 11 (see FIG. 2). The object 11 for which the treatment has been executed by the treatment apparatus 4A is carried out to the conveying unit 10 from the treatment apparatus 4A by the conveying unit 12A.

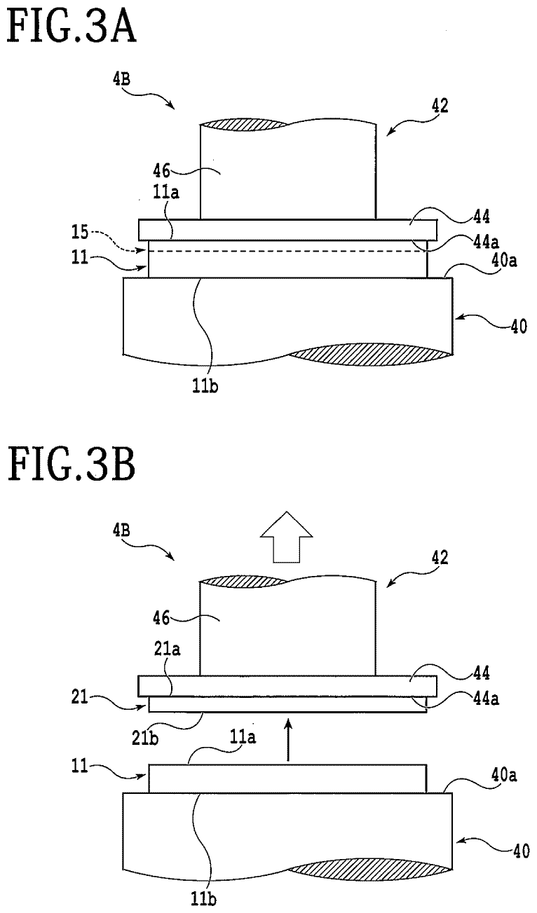

Next, the object 11 is conveyed from the front of the treatment apparatus 4A to the front of the treatment apparatus 4B by the conveying unit 10. Then, the object 11 is carried in to the treatment apparatus 4B from the conveying unit 10 by the conveying unit 12B, and is treated by the treatment apparatus 4B. The treatment apparatus 4B splits off part of the object 11 as described later to manufacture the substrate from the object 11 (see FIGS. 3A and 3B). The object 11 for which the treatment has been executed by the treatment apparatus 4B is carried out to the conveying unit 10 from the treatment apparatus 4B by the conveying unit 12B.

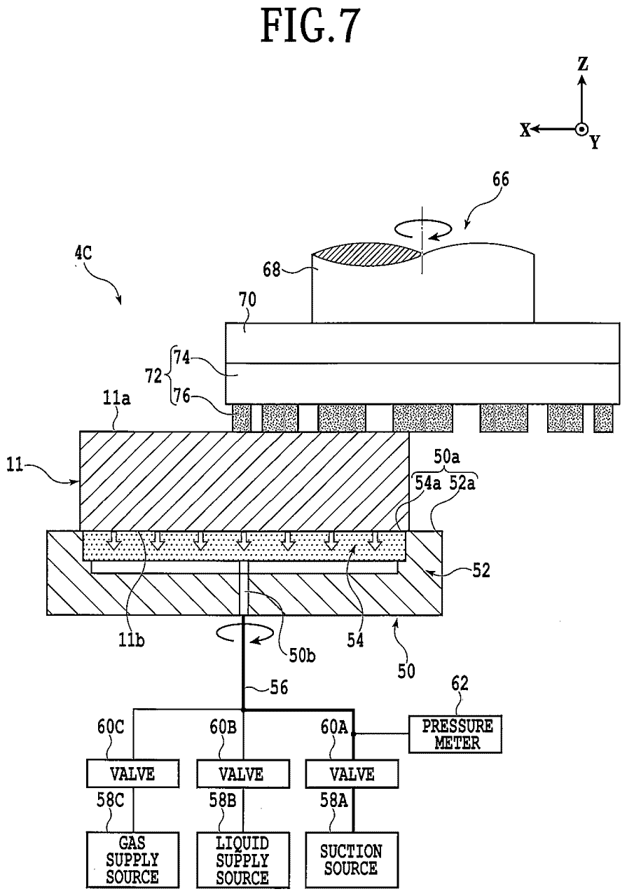

Next, the object 11 is conveyed from the front of the treatment apparatus 4B to a front of the treatment apparatus 4C by the conveying unit 10. Then, the object 11 is carried in to the treatment apparatus 4C from the conveying unit 10 by the conveying unit 12C, and is treated by the treatment apparatus 4C. The treatment apparatus 4C executes grinding processing for the object 11 as described later to planarize a surface of the object 11 (see FIG. 7). The object 11 for which the treatment has been executed by the treatment apparatus 4C is carried out to the conveying unit 10 from the treatment apparatus 4C by the conveying unit 12C.

Then, the object 11 is conveyed to the treatment apparatus 4A again by the conveying units 10 and 12A, and is treated by the treatment apparatus 4A. Thereafter, the object 11 is treated by the treatment apparatuses 4B and 4C by a similar procedure. By repeating the step of treating the object 11 by the treatment apparatuses 4A, 4B, and 4C in turn in this manner, a plurality of substrates are efficiently manufactured from the object 11.

The treatment system 2 can simultaneously treat a plurality of objects 11. For example, while the first object 11 is conveyed to the treatment apparatus 4B and is treated by the treatment apparatus 4B, the second object 11 is conveyed to the treatment apparatus 4A and is treated by the treatment apparatus 4A. Moreover, while the first object 11 is conveyed to the treatment apparatus 4C and is treated by the treatment apparatus 4C, the second object 11 is conveyed to the treatment apparatus 4B and is treated by the treatment apparatus 4B, and the third object 11 is conveyed to the treatment apparatus 4A and is treated by the treatment apparatus 4A. This efficiently treats the plurality of objects 11 and improves productivity.

Next, specific examples of the treatment apparatuses 4A, 4B, and 4C are described. As described above, the treatment apparatus 4A is the laser processing apparatus that executes laser processing for the object 11. The treatment apparatus 4B is the splitting apparatus that splits off the substrate from the object 11. The treatment apparatus 4C is the grinding apparatus that grinds the object 11.

FIG. 2 is a perspective view depicting the treatment apparatus (laser processing apparatus) 4A. The treatment apparatus 4A forms the splitting layer inside the object 11 by executing laser processing for the object 11. In FIG. 2, an X-axis direction (processing feed direction, first horizontal direction, left-right direction) and a Y-axis direction (indexing feed direction, second horizontal direction, front-rear direction) are directions perpendicular to each other. Further, a Z-axis direction (upward-downward direction, height direction, vertical direction) is the direction perpendicular to the X-axis direction and the Y-axis direction.

The object 11 is an ingot formed into a circular column shape or a circular disc shape, and has a first surface (front surface) 11a and a second surface (back surface) 11b substantially parallel to each other and a side surface (outer circumferential surface) 11c connected to the first surface 11a and the second surface 11b. For example, in a case of manufacturing a wafer composed of silicon carbon (SiC), a single-crystal SiC ingot is used as the object 11. The diameter of the ingot is selected depending on the diameter of the wafer to be manufactured (6 inches, 8 inches, or the like). Moreover, a thickness of the ingot is, for example, at least 500 μm and at most 100 mm.

However, a material of the object 11 can be selected as appropriate depending on a material of the wafer to be manufactured. For example, the object 11 may be an ingot composed of silicon, gallium oxide, gallium nitride, lithium tantalate (LT), lithium niobate (LN), diamond, or the like. Further, when the object 11 is composed of a crystalline material, a cutout portion (notch, orientation flat, or the like) indicating a crystal orientation may be made at an outer circumferential portion of the object 11.

The treatment apparatus 4A includes a holding unit 20 that holds the object 11. For example, a chuck table is used as the holding unit 20. An upper surface of the holding unit 20 is a flat surface substantially parallel to a horizontal plane (XY-plane), and forms a circular holding surface 20a that holds the object 11. The holding surface 20a is connected to a suction source (not depicted) such as an ejector through a flow path (not depicted) formed inside the holding unit 20, a valve (not depicted), and the like.

A movement unit (not depicted) that moves the holding unit 20 and a rotational drive source (not depicted) that rotates the holding unit 20 are coupled to the holding unit 20. The movement unit is formed of, for example, a movement mechanism of a ball screw system, and moves the holding unit 20 along the X-axis direction and the Y-axis direction. The rotational drive source is formed of a motor or the like, and rotates the holding unit 20 around a rotation axis substantially parallel to the Z-axis direction.

Moreover, the treatment apparatus 4A includes a treatment unit (laser irradiation unit) 22 that irradiates the object 11 with a laser beam 28. The treatment unit 22 includes a laser oscillator (not depicted) of a YAG laser, a YVO₄ laser, a YLF laser, or the like that emits the laser beam 28 of pulse oscillation, and a housing 24 and a laser processing head 26 disposed over the holding unit 20. The housing 24 is formed into a hollow circular column shape, and is disposed along the Y-axis direction. Further, the laser processing head 26 that emits the laser beam 28 toward the holding unit 20 is mounted on a tip portion of the housing 24.

In the housing 24 and the laser processing head 26, an attenuator that adjusts an output power of the laser beam 28 emitted from the laser oscillator, an optical system that guides the laser beam 28 emitted from the laser oscillator to the object 11 held by the holding unit 20, and the like are housed. The optical system includes optical elements such as a lens, a mirror, a polarizing beam splitter (PBS), a diffractive optical element (DOE), and a liquid-crystal-on-silicon spatial light modulator (LCOS-SLM), and controls a traveling direction, a shape, a focusing position, and the like of the laser beam 28.

In particular, a light collector (not depicted) that is a constituent element of the optical system is housed in the laser processing head 26. The light collector includes a collecting lens such as an fe lens, and focuses the laser beam 28 to irradiate the object 11 with the laser beam 28. Laser processing is executed for the object 11 by the irradiation of the object 11 with the laser beam 28 from the laser processing head 26.

Moreover, an imaging unit 30 that images a subject is mounted on the treatment unit 22. For example, the imaging unit 30 is fixed to the housing 24, and is installed adjacent to the laser processing head 26. The imaging unit 30 includes an image sensor of a charge-coupled devices (CCD) sensor or a complementary metal-oxide-semiconductor (CMOS) sensor, and images the object 11 or the like held by the holding unit 20. There is no limit on the kind of imaging unit 30. For example, a visible light camera or an infrared camera is used as it. A captured image of the object 11 is acquired by imaging the object 11 by the imaging unit 30. Then, position adjustment between the object 11 and the laser processing head 26, check of a state of the object 11, and the like are executed on the basis of the captured image acquired by the imaging unit 30.

A movement unit (not depicted) that moves the housing 24 may be coupled to the housing 24. For example, the movement unit is formed of a movement mechanism of a ball screw system, and moves (raises or lowers) the housing 24 along the Z-axis direction together with the laser processing head 26 and the imaging unit 30. This allows adjustment of a height position of the focal point of the laser beam 28 and focusing of the imaging unit 30.

In the treatment for the object 11 by the treatment apparatus 4A, first, the object 11 is held by the holding unit 20. For example, the object 11 is disposed on the holding unit 20 such that a side of the first surface 11a is exposed upward and the side of the second surface 11b faces the holding surface 20a. When a suction force (negative pressure) of the suction source is made to act on the holding surface 20a in this state, the object 11 is sucked and held by the holding unit 20.

Next, the treatment unit 22 is actuated, and the object 11 is irradiated with the laser beam 28 from the laser processing head 26. Thus, the laser processing is executed for the object 11. Irradiation conditions of the laser beam 28 are set such that the splitting layer that functions as origin of splitting is formed inside the object 11.

Specifically, irradiation conditions of the laser beam 28 are set such that a region irradiated with the laser beam 28 inside the object 11 is modified (altered) and a modified portion (altered portion) 13 is formed. More specifically, a wavelength of the laser beam 28 is set to cause at least part of the laser beam 28 to be transmitted through the object 11. That is, the laser beam 28 has absorbability with respect to the object 11. Further, other irradiation conditions of the laser beam 28 are also set as appropriate such that the modified portion 13 is properly formed in the object 11. For example, when the object 11 is an SiC ingot, irradiation conditions of the laser beam 28 can be set as follows.
Wavelength: 1064 nm
Average output power: 2 to 4.5 W
Repetition frequency: 80 kHz
Processing feed rate: 120 to 260 mm/s

For the irradiation of the object 11 with the laser beam 28, first, the object 11 is imaged by the imaging unit 30, and a captured image of the first surface 11a of the object 11 is acquired. Then, a positional relation between the object 11 and the laser processing head 26 is adjusted on the basis of the captured image. Specifically, a position of the holding unit 20 in the X-axis direction is adjusted to dispose the laser processing head 26 outside the object 11 in the X-axis direction. Moreover, the position of the holding unit 20 in the Y-axis direction is adjusted to cause a position of an end portion of the object 11 in the Y-axis direction to correspond with a position of the laser processing head 26 in the Y-axis direction.

In addition, the height position of the focal point of the laser beam 28 is adjusted to correspond with the height position of the inside of the object 11 (between the first surface 11a and the second surface 11b). A difference in the height position between the first surface 11a of the object 11 and the laser beam 28 at this time corresponds to a depth of the modified portion 13 to be formed inside the object 11.

Then, while the laser beam 28 is emitted from the laser processing head 26, the holding unit 20 is moved along the X-axis direction at a predetermined processing feed rate to relatively move the object 11 and the laser processing head 26 along the X-axis direction (processing feed). Thus, in a state in which the focal point of the laser beam 28 is positioned to the inside of the object 11, irradiation with the laser beam 28 is executed from the side of the first surface 11a of the object 11, and scanning is executed from one end of the object 11 to the other end in the X-axis direction.

When the object 11 is irradiated with the laser beam 28 as described above, the region irradiated with the laser beam 28 inside the object 11 expands and disturbance (distortion) of the crystal structure occurs, and the object 11 is modified. As a result, the modified portion 13 with a linear shape is formed along the X-axis direction inside the object 11.

Thereafter, the holding unit 20 is moved along the Y-axis direction by a predetermined indexing amount (for example, approximately 250 to 400 μm) to relatively move the object 11 and the laser processing head 26 along the Y-axis direction (indexing feed). Then, processing feed is executed while irradiation with the laser beam 28 from the laser processing head 26 is executed by a procedure similar to the above-described procedure. By repeating such work, a plurality of substantially parallel modified portions 13 are formed at predetermined intervals at a predetermined depth position inside the object 11.

The irradiation of the object 11 with the laser beam 28 may be executed only on forward paths of the processing feed, or may be executed on the forward paths and backward paths of the processing feed. Further, scanning with the laser beam 28 may be executed by moving the laser processing head 26 instead of moving the holding unit 20. Moreover, instead of moving the holding unit 20 or the laser processing head 26, a scanning optical system that executes scanning with the laser beam 28 may be mounted on the treatment unit 22. For example, the scanning optical system includes an optical element such as a galvano scanner, an acousto-optic element (AOD), or a polygon mirror.

When scanning with the laser beam 28 is executed in the state in which the focal point of the laser beam 28 is positioned to the predetermined depth position inside the object 11, the object 11 is modified at the focal point and in the vicinity thereof, and the modified portion 13 with the linear shape is formed. Further, an internal stress acts in the modified portion 13, and a plurality of minute cracks occur. The cracks extend from the modified portion 13 along a direction intersecting the thickness direction of the object 11. Moreover, by forming the plurality of modified portions 13 at predetermined intervals, the modified portions 13 and the cracks are formed across the whole of the object 11.

When the modified portions 13 and the cracks are formed in the above-described manner, a splitting layer (modified layer) 15 is formed at the predetermined depth position inside the object 11. The splitting layer 15 corresponds to a region in which the modified portion 13 or the crack is formed inside the object 11. A depth at which the splitting layer 15 is formed in the object 11 (distance between the first surface 11a of the object 11 and the splitting layer 15) corresponds to a thickness of the substrate to be split off from the object 11 by the treatment apparatus 4B (see FIGS. 3A and 3B) in a later step.

The region in which the splitting layer 15 is formed in the object 11 has a lower mechanical strength and is more fragile than the other region in the object 11. Thus, the splitting layer 15 functions as origin of splitting (trigger for splitting) when the substrate is split off from the object 11. Specifically, when an external force is given to the object 11, the side of the first surface 11a of the object 11 breaks, with the splitting layer 15 being origin, and a substrate with the predetermined thickness is split off from the object 11.

A configuration example of the treatment apparatus (splitting apparatus) 4B is depicted in FIGS. 3A and 3B. The treatment apparatus 4B splits off a substrate (plate-shaped object) 21 from the object 11 by giving an external force to the object 11.

The treatment apparatus 4B includes a holding unit 40 that holds the object 11. For example, a chuck table is used as the holding unit 40. An upper surface of the holding unit 40 is a flat surface substantially parallel to the horizontal plane, and forms a circular holding surface 40a that holds the object 11. The holding surface 40a is connected to a suction source (not depicted) such as an ejector through a flow path (not depicted) formed inside the holding unit 40, a valve (not depicted), and the like.

Further, the treatment apparatus 4B includes a treatment unit (splitting unit) 42 disposed over the holding unit 40. The treatment unit 42 includes a holding unit 44 that holds the side of the surface (first surface 11a) on the opposite side to the surface (second surface 11b) held by the holding unit 40 in the object 11. A lower surface of the holding unit 44 is a flat surface substantially parallel to the horizontal plane, and forms a circular holding surface 44a that holds the object 11.

For example, the holding unit 44 is formed of a holding member with a circular disc shape, and has a plurality of suction ports (not depicted) that suck the object 11. One end side of the suction ports opens in the holding surface 44a. The other end side of the suction ports is connected to a suction source (not depicted) such as an ejector through a flow path (not depicted) formed inside the holding unit 44. The number and an arrangement of suction ports are set as appropriate to cause the plurality of suction ports to be closed by the object 11 when the holding surface 44a is in contact with the object 11.

A columnar support member 46 that supports the holding unit 44 is coupled to an upper end side of the holding unit 44. A lower end portion of the support member 46 is fixed to a central portion of the holding unit 44. Moreover, a movement unit (not depicted) that moves the support member 46 is coupled to an upper end side of the support member 46. For example, the movement unit is formed of a movement mechanism of a ball screw system, and moves (raises or lowers) the support member 46 along the vertical direction together with the holding unit 44.

FIG. 3A is a front view depicting the treatment apparatus 4B that holds the object 11. In splitting-off of the substrate from the object 11, first, the object 11 is held by the holding unit 40 and the holding unit 44.

Specifically, the object 11 is disposed on the holding unit 40 in a state in which a space wider than a thickness of the object 11 is ensured between the holding surface 40a of the holding unit 40 and the holding surface 44a of the holding unit 44. At this time, the object 11 is disposed such that the side of the first surface 11a is exposed upward and the side of the second surface 11b faces the holding surface 40a. Then, by making a suction force (negative pressure) of the suction source act on the holding surface 40a, the object 11 is sucked and held by the holding unit 40.

Next, the holding unit 44 is lowered along the vertical direction by the movement unit (not depicted), and the holding surface 44a is brought into contact with the side of the first surface 11a of the object 11. When a suction force (negative pressure) of the suction source is made to act on the holding surface 44a in this state, the object 11 is sucked and held by the holding unit 44. This causes the object 11 to enter a state in which the side of the second surface 11b is fixed to the holding surface 40a and the side of the first surface 11a is fixed to the holding surface 44a.

FIG. 3B is a front view depicting the treatment apparatus 4B that splits off the substrate 21 from the object 11. After the object 11 is fixed to the holding units 40 and 44, the holding unit 44 is raised along the vertical direction by the movement unit (not depicted), with a position of the holding unit 40 fixed. Thus, the holding surfaces 40a and 44a relatively move in such a direction as to separate from each other, and such an external force that the side of the first surface 11a of the object 11 and the side of the second surface 11b are pulled away from each other is given to the object 11. As a result, the object 11 breaks, with the splitting layer 15 being origin, and the substrate 21 corresponding to the side of the first surface 11a of the object 11 is split off from the other portion of the object 11. In this manner, the substrate 21 is manufactured from the object 11.

The substrate 21 has a first surface (front surface) 21a and a second surface (back surface) 21b substantially parallel to each other. The second surface 21b of the substrate 21 corresponds to a splitting surface (breakage surface) formed due to the splitting-off of the substrate 21. Further, a depth at which the splitting layer 15 is formed in the object 11 before the splitting-off of the substrate 21 (distance between the first surface 11a of the object 11 and the splitting layer 15) corresponds to a thickness of the substrate 21 split off from the object 11.

After the substrate 21 is split off from the object 11, the object 11 is used for manufacturing of the substrate 21 again. However, recesses and projections remain as a breakage mark on the side of the first surface 11a (splitting surface, breakage surface) of the object 11 newly formed due to the splitting-off of the substrate 21. Thus, after the substrate 21 is split off from the object 11, the object 11 is ground and planarized by the treatment apparatus 4C.

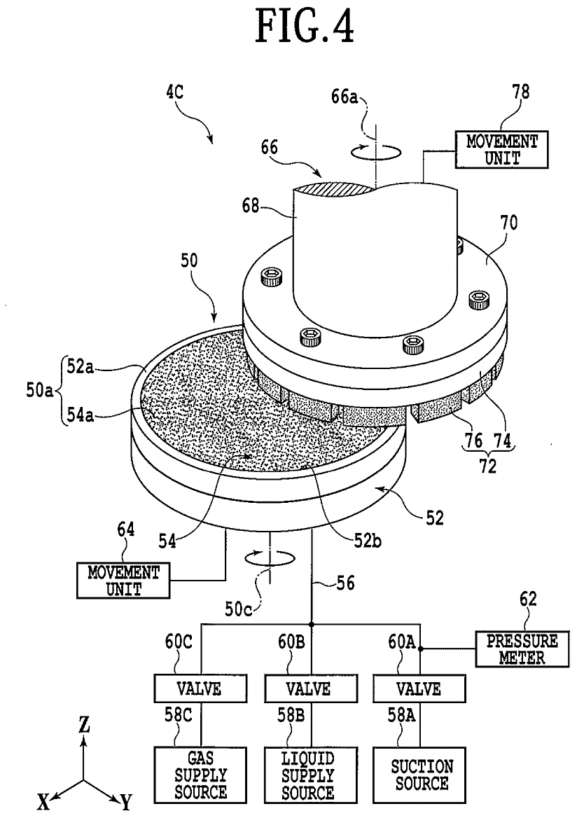

FIG. 4 is a perspective view depicting the treatment apparatus (grinding apparatus) 4C. The treatment apparatus 4C grinds the side of the first surface 11a of the object 11 to remove or reduce the recesses and projections remaining on the side of the first surface 11a of the object 11. In FIG. 4, an X-axis direction (first horizontal direction) and a Y-axis direction (second horizontal direction) are directions perpendicular to each other. Moreover, a Z-axis direction (upward-downward direction, height direction, vertical direction) is the direction perpendicular to the X-axis direction and the Y-axis direction.

The treatment apparatus 4C includes a holding unit 50 that holds the object 11. For example, a chuck table is used as the holding unit 50. An upper surface of the holding unit 50 forms a holding surface 50a that holds the object 11.

Specifically, the holding unit 50 includes a circular columnar frame body (main portion) 52 composed of a metal such as SUS (stainless steel), glass, a ceramic, a resin, or the like. A circular columnar recess portion 52b is made at a central portion of the frame body 52 on a side of an upper surface 52a. Further, a circular disc-shaped holding member 54 composed of a porous material such as a porous ceramic is fitted into the recess portion 52b of the frame body 52. The holding member 54 includes a large number of pores that penetrate the holding member 54 from an upper surface to a lower surface.

The upper surface of the holding member 54 forms a circular suction surface 54a that sucks the object 11 when the object 11 is held by the holding unit 50. The holding surface 50a of the holding unit 50 is formed of the upper surface 52a of the frame body 52 and the suction surface 54a of the holding member 54.

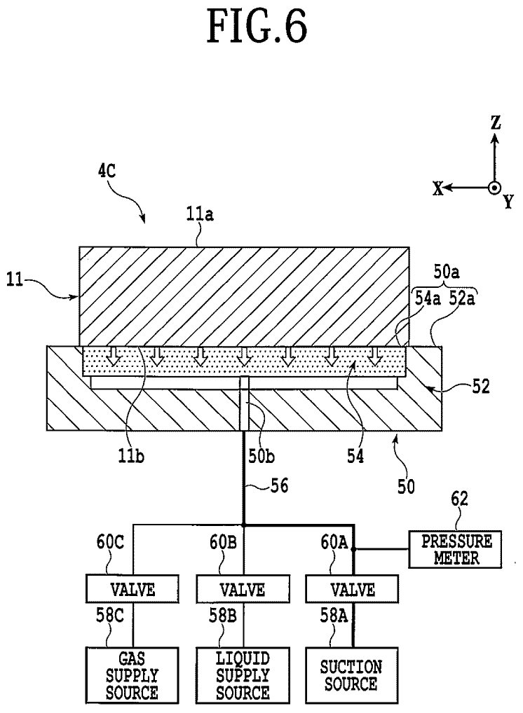

The holding surface 50a is connected to a flow path 56 through pores included in the holding member 54 and a flow path 50b (see FIG. 6 and the like) made inside the frame body 52. The flow path 56 is piping formed of a tube, a pipe, or the like. One end side of the flow path 56 is connected to the holding surface 50a (suction surface 54a) through a rotary joint (not depicted), the flow path 50b (see FIG. 6 and the like) inside the holding unit 50, and the pores included in the holding member 54.

To the other end side of the flow path 56, a suction source 58A such as an ejector, a liquid supply source 58B that supplies a liquid such as water, and a gas supply source 58C that supplies a gas such as air or a nitrogen gas are connected. Moreover, a valve 60A is connected between the flow path 56 and the suction source 58A. A valve 60B is connected between the flow path 56 and the liquid supply source 58B. A valve 60C is connected between the flow path 56 and the gas supply source 58C.

For example, the valves 60A, 60B, and 60C are formed of solenoid valves, and are connected to the controller 6C (see FIG. 1) of the treatment apparatus 4C. Opening and closing of the valves 60A, 60B, and 60C are controlled by outputting a control signal from the controller 6C to the valves 60A, 60B, and 60C. This controls pressure reduction in the flow path 56 by the suction source 58A, whether or not supply of the liquid from the liquid supply source 58B to the flow path 56 is present and a flow rate (supply amount) of the liquid, and whether or not supply of the gas from the gas supply source 58C to the flow path 56 is present and the flow rate (supply amount) of the gas.

When the valve 60A is opened in a state in which the valves 60B and 60C are closed, a suction force (negative pressure) of the suction source 58A acts on the holding surface 50a. This can suck and hold the object 11 disposed on the holding surface 50a.

When the valve 60B is opened in a state in which the valves 60A and 60C are closed, the liquid is supplied from the liquid supply source 58B to the flow path 56 at a predetermined flow rate, and can be ejected from the holding surface 50a. Further, when the valve 60C is opened in a state in which the valves 60A and 60B are closed, the gas is supplied from the gas supply source 58C to the flow path 56 at a predetermined flow rate, and can be ejected from the holding surface 50a. Moreover, when the valves 60B and 60C are opened in a state in which the valve 60A is closed, the liquid supplied from the liquid supply source 58B and the gas supplied from the gas supply source 58C are mixed in the flow path 56, and a mixed fluid containing the liquid and the gas can be ejected from the holding surface 50a.

Further, a pressure meter 62 that measures a pressure in the flow path 56 is connected to the flow path 56. The pressure meter 62 measures the pressure in the flow path 56 constantly or at a predetermined timing, and outputs the pressure to the controller 6C (see FIG. 1). Thus, the pressure in the flow path 56 is monitored by the controller 6C. In addition, the controller 6C can determine whether or not the state of holding of the object 11 by the holding unit 50 is proper (whether or not the object 11 is being properly sucked and held, whether or not suction holding of the object 11 has been properly canceled, or the like) on the basis of the pressure measured by the pressure meter 62.

Moreover, a movement unit 64 that moves the holding unit 50 along a horizontal direction (XY-plane direction) is coupled to the holding unit 50. For example, the movement unit 64 is formed of a movement mechanism of a ball screw system, a turntable, or the like. The holding unit 50 can be moved along the horizontal direction and be disposed at a desired position by outputting the control signal from the controller 6C (see FIG. 1) to the movement unit 64.

Further, a rotational drive source (not depicted) such as a motor that rotates the holding unit 50 around a rotation axis 50c is coupled to the holding unit 50. The rotation axis 50c of the holding unit 50 is set along a direction perpendicular to a radial direction of the holding surface 50a, and intersects the holding surface 50a in such a manner as to pass through a center of the holding surface 50a.

Moreover, the treatment apparatus 4C includes a treatment unit (grinding unit) 66 that grinds the object 11. The treatment unit 66 is disposed over the holding unit 50, and includes a circular columnar spindle 68 disposed along the Z-axis direction. A circular disc-shaped wheel mount 70 composed of a metal such as SUS (stainless steel) is fixed to a tip portion (lower end portion) of the spindle 68. Further, a rotational drive source (not depicted) such as a motor is coupled to a base end portion (upper end portion) of the spindle 68.

An annular grinding wheel 72 that grinds the object 11 is mounted on a lower surface side of the wheel mount 70. For example, the grinding wheel 72 is attachably/detachably fixed to the wheel mount 70 by a fixing element such as a bolt.

The grinding wheel 72 includes an annular wheel base 74. The wheel base 74 is composed of a metal such as aluminum or stainless steel, and is formed to have substantially the same diameter as the wheel mount 70. An upper surface side of the wheel base 74 is fixed to the lower surface side of the wheel mount 70. Moreover, a plurality of grinding abrasive stones 76 are fixed to the lower surface side of the wheel base 74. For example, the grinding abrasive stones 76 are formed into a rectangular parallelepiped shape, and are annularly arranged at substantially equal intervals along the outer circumferential edge of the wheel base 74. Lower surfaces of the grinding abrasive stones 76 form a grinding surface that grinds the object 11.

The grinding abrasive stones 76 are formed by binding abrasive grains composed of diamond, cubic boron nitride (cBN), or the like by a binding material (bond material) such as a metal bond, a resin bond, or a vitrified bond. There is no limit on the material, shape, structure, size, and the like of the grinding abrasive stones 76. Further, the number of grinding abrasive stones 76 can also be set to any number.

When the rotational drive source coupled to the spindle 68 is actuated, the spindle 68, the wheel mount 70, and the grinding wheel 72 rotate around a rotation axis 66a substantially parallel to the Z-axis direction. Thus, the plurality of grinding abrasive stones 76 each turn along an annular turning path substantially parallel to the horizontal plane (XY-plane) around the rotation axis 66a.

Further, a movement unit 78 that moves (raises or lowers) the treatment unit 66 along the Z-axis direction is coupled to the treatment unit 66. For example, the movement unit 78 is formed of a movement mechanism of a ball screw system. By outputting the control signal from the controller 6C (see FIG. 1) to the movement unit 78, the movement unit 78 is actuated and the treatment unit 66 rises or lowers. Thus, the holding unit 50 and the grinding wheel 72 relatively move along the Z-axis direction, and the holding surface 50a of the holding unit 50 gets closer to or farther away from the grinding wheel 72.

After the substrate 21 is split off from the object 11 by the treatment apparatus 4B (see FIG. 3B), the side of the first surface 11a of the object 11 is ground by the treatment apparatus 4C. Thus, the recesses and projections remaining on the side of the first surface 11a (splitting surface, breakage surface) of the object 11 are removed or reduced, and the side of the first surface 11a of the object 11 is planarized. Thereafter, the object 11 is reused for formation of the next substrate 21.

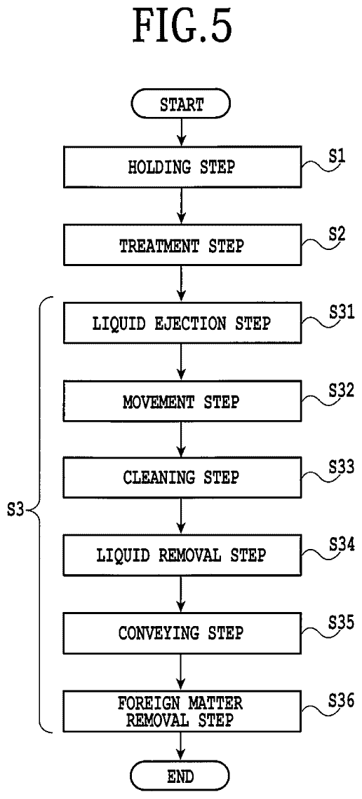

Next, a description is given of a specific example of the treatment method for an object by which the object 11 is treated. In the present embodiment, a procedure of treating the object 11 by the treatment apparatus 4C is described as a representative example. FIG. 5 is a flowchart depicting the treatment method for an object.

The treatment method for an object according to the present embodiment includes a holding step S1 of holding the object 11 by the holding surface 50a of the holding unit 50, a treatment step S2 of treating the object 11 by the treatment unit 66, and a separation step S3 of separating the object 11 from the holding surface 50a. The separation step S3 corresponds to the separation method for an object according to the present embodiment. Details of each step are described below.

First, the object 11 is held by the holding surface 50a (holding step S1). FIG. 6 is a sectional view depicting the treatment apparatus 4C in the holding step S1. In the holding step S1, the object 11 is sucked and held by the holding surface 50a of the holding unit 50 included in the treatment apparatus 4C.

Specifically, first, the object 11 is conveyed by a predetermined conveying unit (not depicted), and is disposed on the holding surface 50a of the holding unit 50. At this time, the object 11 is disposed on the holding unit 50 such that the first surface 11a (ground surface) is exposed upward and the second surface 11b (held surface) faces the holding surface 50a. Moreover, the object 11 is disposed concentrically with the holding surface 50a such that the whole of the suction surface 54a is covered by the second surface 11b of the object 11.

Then, the valve 60A is opened in a state in which the valves 60B and 60C are closed. Thus, the suction source 58A is coupled to the suction surface 54a through the flow paths 56 and 50b and the pores inside the holding member 54, and the suction force (negative pressure) of the suction source 58A acts on the suction surface 54a and the second surface 11b of the object 11. As a result, the object 11 is sucked and held by the holding surface 50a.

When the object 11 is held by the holding surface 50a, a protective sheet (not depicted) that protects the object 11 may be applied to the side of the second surface 11b of the object 11. For example, as the protective sheet, a tape in which an adhesive layer is formed on a base, a thermocompression bonding sheet that does not include an adhesive layer and can be thermocompression-bonded to the object 11, or the like is used. In this case, the object 11 is sucked and held by the holding surface 50a, with the protective sheet interposed therebetween.

Next, the object 11 held by the holding surface 50a is treated (treatment step S2). FIG. 7 is a partially sectional front view depicting the treatment apparatus 4C in the treatment step S2. In the treatment step S2, the object 11 is ground by the treatment unit 66.

Specifically, first, the holding unit 50 is positioned below the treatment unit 66. At this time, a positional relation between the holding unit 50 and the treatment unit 66 is adjusted such that the rotation axis of the holding unit 50 (center of the object 11) overlaps with a turning path of the grinding abrasive stones 76 in the Z-axis direction. Then, the treatment unit 66 is lowered along the Z-axis direction while the holding unit 50 and the grinding wheel 72 are rotated at a predetermined speed. Thus, the plurality of grinding abrasive stones 76 approach the object 11 while turning, and get contact with the side of the first surface 11a of the object 11.

Upon contact of the plurality of grinding abrasive stones 76 with the side of the first surface 11a of the object 11, the side of the first surface 11a of the object 11 is scraped off and ground. This removes or reduces the recesses and projections remaining on the side of the first surface 11a of the object 11, and the side of the first surface 11a of the object 11 is planarized. Then, the object 11 is ground and thinned to the predetermined thickness, and thereafter the treatment unit 66 rises and the grinding is stopped.

During the grinding of the object 11, a liquid (grinding liquid) such as purified water is supplied to the ground surface (first surface 11a) of the object 11 and the grinding abrasive stones 76. This cools the object 11 and the grinding abrasive stones 76, and washes off processing dust generated due to the grinding of the object 11.

When the grinding of the object 11 has been completed, the object 11 is carried out from the treatment apparatus 4C. Specifically, the separation step S3 of separating the object 11 from the holding surface 50a of the holding unit 50 and carrying out the object 11 from the treatment apparatus 4C is executed. Details of the separation step S3 are described below.

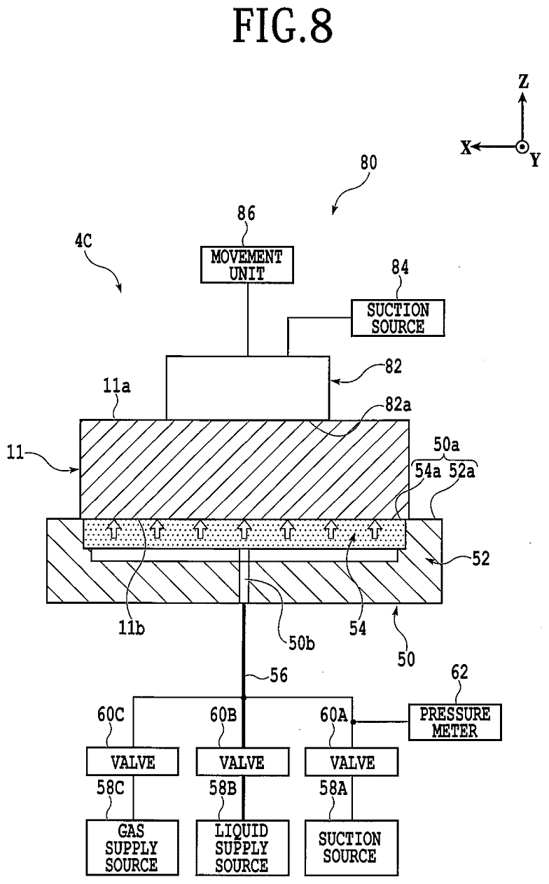

In the separation step S3, first, a liquid is ejected from the holding surface 50a in a state in which the object 11 is held by the holding surface 50a (liquid ejection step S31). FIG. 8 is a partially sectional front view depicting the treatment apparatus 4C in the liquid ejection step S31.

The treatment apparatus 4C includes a conveying unit 80 that conveys the object 11. The conveying unit 80 includes a holding unit 82 that holds the side of the surface (first surface 11a) on the opposite side to the surface (second surface 11b) held by the holding surface 50a in the object 11. A lower surface of the holding unit 82 is a flat surface substantially parallel to the horizontal plane (XY-plane), and forms a holding surface 82a that holds the object 11.

For example, the holding unit 82 is formed of a holding member with a circular column shape, and has a plurality of suction ports (not depicted) that suck the object 11. One end side of the suction ports opens in the holding surface 82a. Meanwhile, the other end side of the suction ports is connected to a suction source 84 such as an ejector through a flow path (not depicted) formed inside the holding unit 82. The number and the arrangement of suction ports are set as appropriate to cause the plurality of suction ports to be closed by the object 11 when the holding surface 82a is in contact with the object 11.

There is no limit on the kind, configuration, and the like of the holding unit 82 as long as the object 11 can be held by the holding unit 82. For example, the holding unit 82 may include a plurality of suction pads that suck the object 11. In this case, the plurality of suction pads are each connected to the suction source 84. Further, the holding unit 82 may include a clamp mechanism that grasps and holds the object 11.

A movement unit 86 that moves the holding unit 82 along the horizontal direction (XY-plane direction) and the vertical direction (Z-axis direction) is coupled to the holding unit 82. For example, the movement unit 86 includes a movement mechanism (movement mechanism of a ball screw system, conveying arm, or the like) that moves the holding unit 82 along the horizontal direction and a raising/lowering mechanism (movement mechanism of a ball screw system, linear actuator, air cylinder, or the like) that moves the holding unit 82 along the Z-axis direction. Moreover, the movement unit 86 may be a conveying robot such as an articulated robot that can move the holding unit 82 to any position.

In the liquid ejection step S31, first, the object 11 is held by the conveying unit 80. Specifically, the holding unit 82 is moved by the movement unit 86, and is positioned directly above the object 11. Next, the holding unit 82 is lowered along the Z-axis direction by the movement unit 86, and the holding surface 82a is brought into contact with the side of the first surface 11a of the object 11. When a suction force (negative pressure) of the suction source 84 is made to act on the holding surface 82a in this state, the object 11 is sucked and held by the holding surface 82a.

Next, the valve 60A is closed and the valve 60B is opened, with the valve 60C kept closed. Thus, a coupling between the flow path 56 and the suction source 58A is interrupted, and the liquid supply source 58B is coupled to the flow path 56. As a result, a vacuum in the flow paths 50b and 56 is released and a pressure in the flow paths 50b and 56 rises. In addition, the liquid is supplied from the liquid supply source 58B to the flow path 56.

The liquid supplied to the flow path 56 is supplied to the holding surface 50a (suction surface 54a) through the flow path 50b and the pores inside the holding member 54, and is ejected from the holding surface 50a toward the side of the second surface 11b of the object 11. This makes it easier for the object 11 to separate from the holding surface 50a, and separation of the object 11 from the holding surface 50a is assisted.

Further, the liquid is continuously supplied to the side of the second surface 11b of the object 11 by ejecting the liquid from the holding surface 50a for a predetermined period in the liquid ejection step S31. Due to this, the side of the second surface 11b of the object 11 is cleaned, and foreign matters (processing dust, particles, and the like) adhering to the side of the second surface 11b of the object 11 are removed.

When a flow rate of the liquid supplied from the liquid supply source 58B to the flow path 56 is sufficiently high in view of a suction force of the suction source 58A, the liquid can be ejected from the holding surface 50a even when the flow path 56 and the suction source 58A remain coupled. In this case, the valve 60A is not necessarily required to be closed to interrupt the coupling between the flow path 56 and the suction source 58A.

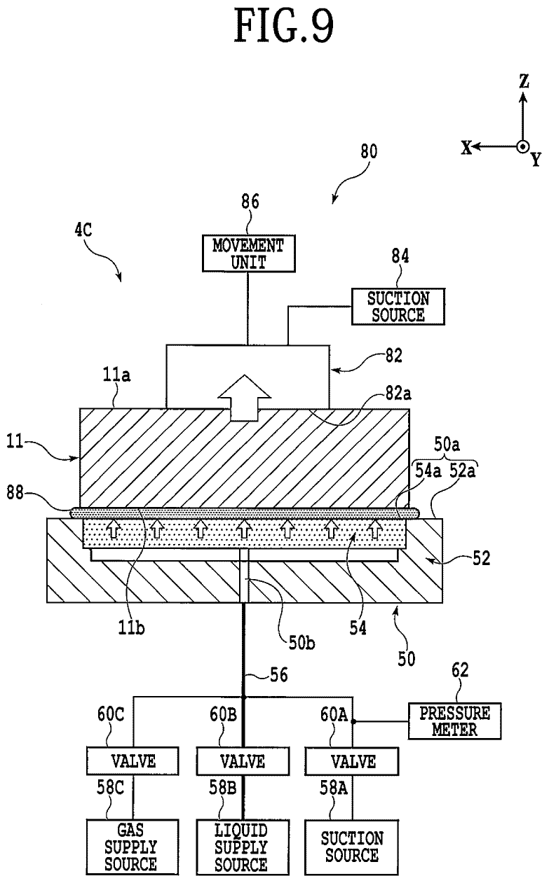

Next, by causing the holding surface 50a and the object 11 to relatively move in such a direction as to separate from each other, the holding surface 50a and the object 11 are separated while a state in which the liquid is in contact with both the holding surface 50a and the object 11 is kept (movement step S32). FIG. 9 is a partially sectional front view depicting the treatment apparatus 4C in the movement step S32.

In the movement step S32, in a state in which a liquid 88 such as water is ejected from the holding surface 50a, the holding unit 82 is slightly raised along a direction intersecting the holding surface 50a (Z-axis direction) by the movement unit 86. Thus, the holding surface 50a and the object 11 relatively move in such a direction as to separate from each other, and the object 11 separates from the holding surface 50a while being pushed up by the liquid 88. At this time, the liquid 88 is continuously ejected from the holding surface 50a, and thus remains between the holding surface 50a and the object 11.

In the movement step S32, an amount of relative movement between the holding surface 50a and the object 11 (amount of rise of the holding unit 82) is set such that a state in which the liquid 88 is in contact with both the holding surface 50a and the object 11 is kept. Thus, immediately after the object 11 separates from the holding surface 50a, the liquid 88 enters a gap between the holding surface 50a and the object 11, and the state in which the liquid 88 is in contact with the holding surface 50a and the second surface 11b of the object 11 is kept. The amount of relative movement between the holding surface 50a and the object 11 (gap between the holding surface 50a and the object 11) in the movement step S32 is set as appropriate depending on nature of the object 11 and the liquid 88 (hydrophilicity and the like), and is, for example, at least 2 mm and at most 4 mm.

By keeping on ejecting the liquid 88 from the holding surface 50a during execution of the movement step S32, the liquid 88 is continuously supplied to the side of the second surface 11b of the object 11. This can clean the side of the second surface 11b of the object 11 also in the movement step S32 following the liquid ejection step S31.

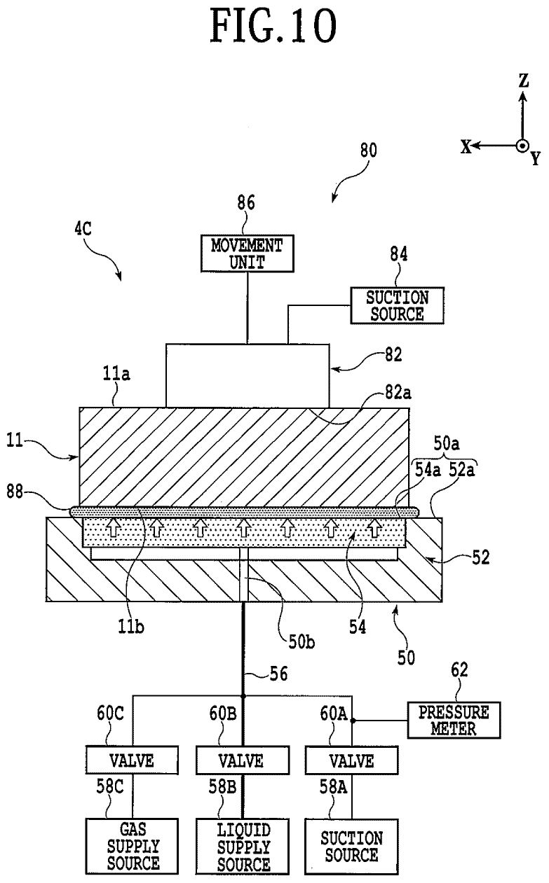

Next, in a state in which the relative movement between the holding surface 50a and the object 11 is stopped, the object 11 is cleaned by the liquid 88 ejected from the holding surface 50a (cleaning step S33). FIG. 10 is a partially sectional front view depicting the treatment apparatus 4C in the cleaning step S33.

When the cleaning of the object 11 is insufficient in the above-described liquid ejection step S31 (see FIG. 8) and movement step S32 (see FIG. 9), the cleaning step S33 of additionally cleaning the side of the second surface 11b of the object 11 is executed as required. Specifically, ejection of the liquid 88 from the holding surface 50a is continued for a certain time in a state in which the rise of the holding unit 82 is suspended and the relative movement between the holding surface 50a and the object 11 is stopped. Thus, the supply of the liquid 88 to the side of the second surface 11b of the object 11 is continued, and a cleaning time of the object 11 is extended.

The cleaning time of the object 11 (supply time of the liquid 88) in the cleaning step S33 is set as appropriate depending on the state of the object 11. For example, the cleaning time of the object 11 is at least five seconds and at most one minute, and preferably at least 10 seconds and at most 30 seconds. Moreover, in the cleaning step S33, the flow rate of the liquid supplied from the liquid supply source 58B to the flow path 56, that is, the flow rate of the liquid ejected from the holding surface 50a, may be set higher than that in the liquid ejection step S31 and the movement step S32. For example, the flow rate of the liquid in the cleaning step S33 is equal to or higher than 1.2 times, preferably 1.5 times, more preferably twice, the flow rate of the liquid in the liquid ejection step S31 and the movement step S32.

The valve 60C may be opened in addition to the valve 60B in the liquid ejection step S31 (see FIG. 8), the movement step S32 (see FIG. 9), and the cleaning step S33 (see FIG. 10). In this case, the liquid 88 supplied from the liquid supply source 58B and the gas supplied from the gas supply source 58C are mixed in the flow path 56, and a mixed fluid containing the liquid 88 and the gas is generated. Then, the mixed fluid is ejected from the holding surface 50a toward the object 11. Due to this, compared with a case in which only the liquid 88 is ejected from the holding surface 50a, the liquid 88 vigorously impinges on the object 11, and the separation of the object 11 from the holding surface 50a and the cleaning of the object 11 are further promoted.

However, when the object 11 is comparatively thin (for example, thickness is 100 mm or smaller), it is preferable to keep a state in which the valve 60C is closed to eject only the liquid 88 from the holding surface 50a and keep the gas from being ejected from the holding surface 50a. In this case, the liquid 88 ejected from the holding surface 50a is less likely to be splashed, and adhesion of the liquid 88 to the side of the first surface 11a of the object 11 can be avoided. Thus, when the object 11 is processed by the treatment apparatus 4A again in a later step (see FIG. 2), inhibition of laser processing due to the liquid 88 adhering to the side of the first surface 11a of the object 11 can be prevented.

Further, the cleaning step S33 may be omitted in a case in which the object 11 is sufficiently cleaned by the liquid 88 supplied to the object 11 in the liquid ejection step S31 and the movement step S32. In this case, after the relative movement between the holding surface 50a and the object 11 is stopped in the above-described movement step S32, immediately the following liquid removal step S34 is executed.

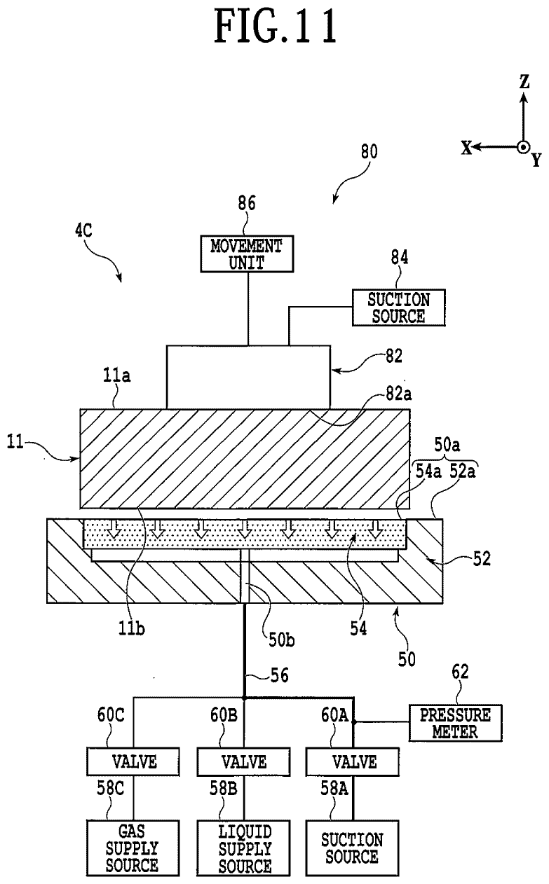

Next, the liquid 88 in contact with both the holding surface 50a and the object 11 is removed (liquid removal step S34). FIG. 11 is a partially sectional front view depicting the treatment apparatus 4C in the liquid removal step S34.

The treatment apparatus 4C includes a removal unit that removes the liquid 88 ejected from the holding surface 50a. In the present embodiment, the removal unit is configured by the holding surface 50a, the flow path 56 connected to the holding surface 50a, and the suction source 58A and the valve 60A connected to the flow path 56. Moreover, in separation of the object 11 from the holding surface 50a, the controller 6C (see FIG. 1) of the treatment apparatus 4C controls the removal unit to cause the removal unit to remove the liquid 88 in contact with both the holding surface 50a and the object 11.

Specifically, in a state in which the rise of the holding unit 82 is stopped, the control signal is output from the controller 6C to the valves 60A, 60B, and 60C, and the valves 60B and 60C are closed and the valve 60A is opened. Thus, the holding surface 50a and the suction source 58A are coupled, and the suction force (negative pressure) of the suction source 58A acts on the holding surface 50a. As a result, the liquid 88 (see FIG. 10) in contact with the holding surface 50a and the object 11 is sucked by the holding surface 50a, and is removed from between the holding surface 50a and the object 11.

If the liquid 88 remaining between the holding surface 50a and the object 11 is left as it is, surface tension of the liquid 88 acts on the object 11, and a state in which the object 11 is attracted by the holding surface 50a through the liquid 88 is made. Thus, in separation of the object 11 from the holding surface 50a, the object 11 is required to be carefully lifted up by a strong force and be pulled away from the holding surface 50a. Therefore, smooth conveyance of the object 11 is hindered. Further, when the strong external force is given to the object 11, there is a possibility that deformation or damage of the object 11 occurs.

On the other hand, when the liquid removal step S34 is executed as in the present embodiment, the liquid 88 that hinders detachment of the object 11 from the holding surface 50a is removed from between the holding surface 50a and the object 11. This makes it possible to vanish the surface tension of the liquid 88 acting on the object 11 and easily separate the object 11 from the holding surface 50a.

In the above description, the example in which the holding surface 50a is caused to suck the liquid 88 by the suction force of the suction source 58A has been described. However, there is no limit on the configuration of the removal unit that removes the liquid 88 in the liquid removal step S34.

For example, the treatment apparatus 4C may include, as the removal unit, a nozzle (not depicted) that blows a gas such as air into a gap between the holding surface 50a and the object 11. In this case, the liquid 88 can be removed by controlling the nozzle by the controller 6C (see FIG. 1) to jet the gas from the nozzle to the liquid 88 remaining between the holding surface 50a and the object 11. Moreover, the liquid 88 may be blown off to be removed by opening the valve 60C in a state in which the valves 60A and 60B are closed and ejecting the gas from the holding surface 50a. In this case, the removal unit is configured by the holding surface 50a, the flow path 56 connected to the holding surface 50a, and the gas supply source 58C and the valve 60C connected to the flow path 56.

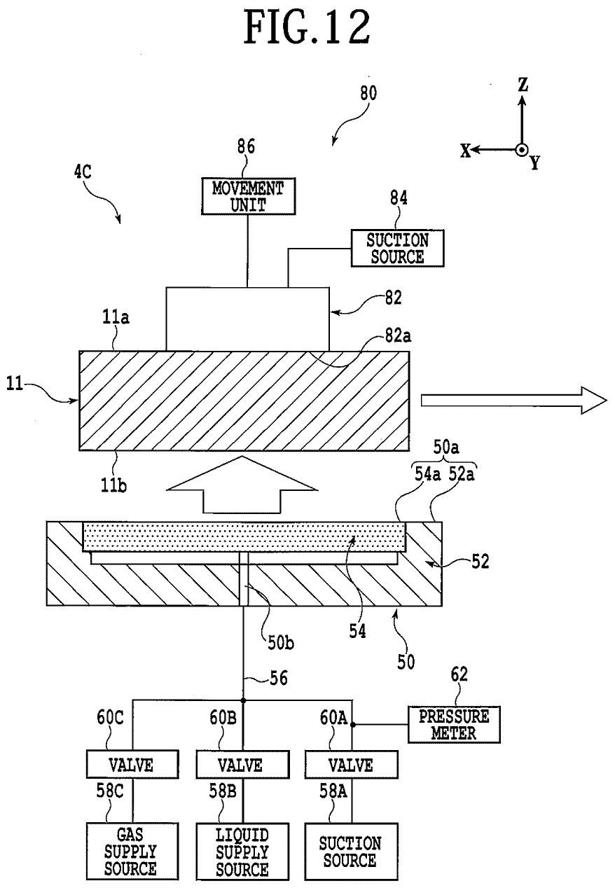

After the liquid 88 is removed in the liquid removal step S34, the object 11 is conveyed from above the holding surface 50a (conveying step S35). FIG. 12 is a partially sectional front view depicting the treatment apparatus 4C in the conveying step S35.

In the conveying step S35, after the valve 60A is closed to cancel the suction force acting on the holding surface 50a, the object 11 is conveyed by moving the holding unit 82 by the movement unit 86. For example, first, the object 11 is further separated from the holding surface 50a by raising the holding unit 82 along the Z-axis direction by the movement unit 86. At this time, the liquid 88 does not remain between the holding surface 50a and the object 11. Thus, the separation of the object 11 from the holding surface 50a is not inhibited by the surface tension of the liquid 88.

Thereafter, the holding unit 82 is moved along the horizontal direction (XY-plane direction) by the movement unit 86. Thereby, the object 11 leaves a region directly above the holding surface 50a (region overlapping with the holding surface 50a in the Z-axis direction), and is carried out to the external of the treatment apparatus 4C through the conveying port (not depicted) of the treatment apparatus 4C.

In the series of processes from the holding step S1 to the conveying step S35, foreign matters (processing dust, particles, and the like) existing in the treatment apparatus 4C sometimes adhere to the holding surface 50a or enter the inside of the holding unit 50 from the holding surface 50a. In particular, the adherence or entry of the foreign matters is likely to occur in the steps of causing the suction force to act on the holding surface 50a (see FIG. 6, FIG. 11, and the like). Thus, the foreign matters may be removed from the holding unit 50 by ejecting a fluid from the holding surface 50a after the object 11 is separated from the holding surface 50a (foreign matter removal step S36).

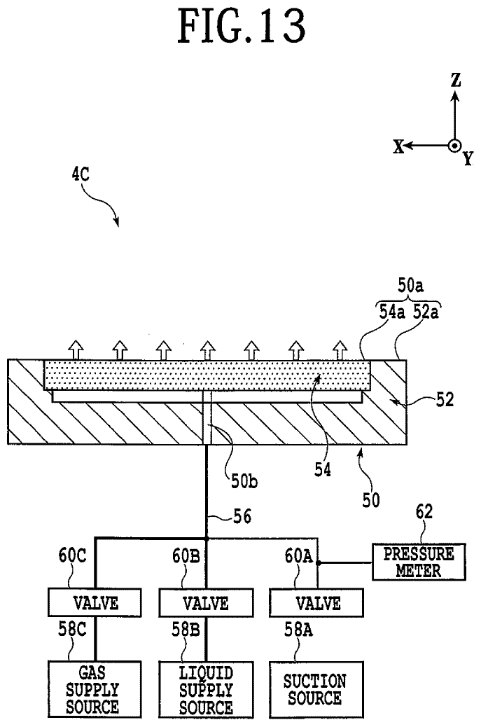

FIG. 13 is a sectional view depicting the treatment apparatus 4C in the foreign matter removal step S36. For example, in the foreign matter removal step S36, the valves 60B and 60C are opened in a state in which the valve 60A is closed. Thus, a mixed fluid containing the liquid and the gas is generated in the flow path 56, and is ejected from the holding surface 50a. At this time, the foreign matters inside the holding unit 50 or on the holding surface 50a are swept away by the mixed fluid, and are discharged from the holding surface 50a to the external of the holding unit 50. This removes the foreign matters from the holding unit 50.

In the foreign matter removal step S36, the foreign matters may be removed by only the liquid through opening the valve 60B in a state in which the valves 60A and 60C are closed. Alternatively, the foreign matters may be removed by only the gas through opening the valve 60C in a state in which the valves 60A and 60B are closed.

A timing of the ejection of the fluid (liquid, gas, or mixed fluid) from the holding surface 50a in the foreign matter removal step S36 can be freely set as long as being after the separation of the object 11 from the holding surface 50a. However, in particular, it is preferable to execute the foreign matter removal step S36 after the object 11 has left the region directly above the holding surface 50a (region overlapping with the holding surface 50a in the Z-axis direction) in the conveying step S35. Due to this, even when foreign matters discharged from the holding surface 50a are scattered upward, the foreign matters are less likely to adhere to the object 11. Further, in order to surely avoid the adherence of foreign matters to the object 11, the foreign matter removal step S36 may be executed after the object 11 is carried out from a treatment chamber (space in which grinding processing is executed) of the treatment apparatus 4C or after the object 11 is carried out from the treatment apparatus 4C.

The object 11 is treated by the treatment apparatus 4C in the above-described manner. The steps from the holding step S1 to the foreign matter removal step S36 are implemented by executing a program stored in the controller 6C (see FIG. 1) of the treatment apparatus 4C. Specifically, the program for actuating each constituent element of the treatment apparatus 4C such that the steps from the holding step S1 to the foreign matter removal step S36 are sequentially executed is stored in the storage section (memory) of the controller 6C. Moreover, the controller 6C receives an instruction from the host computer 14 (see FIG. 1) to execute the above-described program. This causes the steps from the holding step S1 to the foreign matter removal step S36 to be automatically executed by the treatment apparatus 4C.

The object 11 treated by the treatment apparatus 4C is carried out to the treatment apparatus 4A again by the conveying system 8 (see FIG. 1). Then, the treatments by the treatment apparatuses 4A, 4B, and 4C are repeated in turn, and thereby a plurality of substrates 21 are sequentially split off from the object 11.

Polishing processing may be executed for the object 11 before the object 11 for which the grinding processing has been executed by the treatment apparatus 4C is conveyed to the treatment apparatus 4A. Specifically, the treatment system 2 (FIG. 1) may include a treatment apparatus (polishing apparatus) that executes the polishing processing for the object 11. In this case, after the grinding processing is executed for the side of the first surface 11a of the object 11, subsequently the polishing processing is executed for the side of the first surface 11a of the object 11. This can turn the side of the first surface 11a of the object 11 to a mirror surface.

For example, the polishing apparatus includes a holding unit having a holding surface that holds the object 11 and a treatment unit (polishing unit) that executes the polishing processing for the object 11 held by the holding unit. The polishing unit includes a spindle, and a polishing pad with a circular disc shape is mounted on a tip portion of the spindle. The object 11 is polished by holding the object 11 by the holding surface and bringing the polishing pad into contact with the object 11 while rotating the holding unit and the polishing pad.

As described above, in the separation method for an object, the treatment method for an object, and the treatment apparatus 4C according to the present embodiment, the liquid 88 in contact with both the holding surface 50a and the object 11 is removed in separation of the object 11 from the holding surface 50a. This makes it possible to vanish the surface tension of the liquid 88 acting on the object 11 and easily and properly separate the object 11 from the holding surface 50a.

In the above-described embodiment, the example in which the steps from the holding step S1 to the separation step S3 are executed by the treatment apparatus 4C has been described. However, it is also possible to apply the steps from the holding step S1 to the separation step S3 to the treatments for the object 11 by the treatment apparatuses 4A and 4B.

For example, the holding unit 20 (see FIG. 2) of the treatment apparatus 4A and the holding unit 40 (see FIGS. 3A and 3B) of the treatment apparatus 4B are configured similarly to the holding unit 50 (see FIG. 4) of the treatment apparatus 4C. Further, the flow path 56, the suction source 58A, the liquid supply source 58B, the gas supply source 58C, and the valves 60A, 60B, and 60C (see FIG. 4) are connected to the holding units 20 and 40.

Then, the treatment apparatuses 4A and 4B execute the steps from the holding step S1 to the separation step S3 similarly to the treatment apparatus 4C. In this case, the treatment apparatus 4A executes laser processing (see FIG. 2) for the object 11 in the treatment step S2, and can execute the holding step S1 and the separation step S3 similarly to the treatment apparatus 4C. The treatment apparatus 4B executes the treatment of splitting off the substrate 21 from the object 11 (see FIGS. 3A and 3B) in the treatment step S2, and can execute the holding step S1 and the separation step S3 similarly to the treatment apparatus 4C. Moreover, when the treatment system 2 (FIG. 1) includes another treatment apparatus (polishing apparatus or the like), the steps from the holding step S1 to the separation step S3 may be executed in the treatment apparatus.

Further, in the present embodiment, the example in which the object 11 that is an ingot is treated by the treatment system 2 has been described. However, it is also possible to apply the treatment method for an object according to the present invention to another object and another treatment apparatus.

For example, in a manufacturing process for device chips, the device chips are manufactured by dividing a wafer composed of a semiconductor material such as silicon. For the dividing of the wafer, a treatment apparatus (cutting apparatus) that cuts the object by an annular cutting blade is used.

The cutting apparatus includes a holding unit having a holding surface that holds the object and a treatment unit (cutting unit) that executes cutting processing for the object held by the holding unit. The cutting unit includes a spindle, and the annular cutting blade is mounted on a tip portion of the spindle. The wafer is cut and divided by holding the wafer by the holding surface and causing the cutting blade to cut into the wafer while rotating the cutting blade.

The steps from the holding step S1 to the separation step S3 can be applied also to the cutting processing for the wafer by the cutting apparatus. This makes it possible to easily and properly separate the wafer resulting from the cutting processing from the holding surface of the holding unit.

Besides, structures, methods, and the like according to the above-described embodiment can be carried out with appropriate changes without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A separation method for an object by which the object held by a holding surface is separated from the holding surface, the separation method comprising:
ejecting a liquid from the holding surface in a state in which the object is held by the holding surface;
separating the holding surface and the object while keeping a state in which the liquid is in contact with both the holding surface and the object by causing the holding surface and the object to relatively move in such a direction as to separate from each other after the ejecting the liquid from the holding surface; and
removing the liquid in contact with both the holding surface and the object after the separating the holding surface and the object.

2. The separation method for an object according to claim 1, wherein,
in the removing the liquid, the liquid in contact with both the holding surface and the object is removed by sucking the liquid by the holding surface.

3. The separation method for an object according to claim 1, wherein
the object is cleaned by the liquid ejected from the holding surface in the ejecting the liquid from the holding surface or in the separating the holding surface and the object.

4. The separation method for an object according to claim 1, further comprising:
cleaning the object by the liquid ejected from the holding surface in a state in which the relative movement between the holding surface and the object is stopped after the separating the holding surface and the object and before the removing the liquid in contact with both the holding surface and the object.

5. A treatment method for an object by which the object is treated, the treatment method comprising:
holding the object by a holding surface;
treating the object held by the holding surface after the holding the object by the holding surface;
ejecting a liquid from the holding surface in a state in which the object is held by the holding surface after the treating the object;
separating the holding surface and the object while keeping a state in which the liquid is in contact with both the holding surface and the object by causing the holding surface and the object to relatively move in such a direction as to separate from each other after the ejecting the liquid from the holding surface; and
removing the liquid in contact with both the holding surface and the object after the separating the holding surface and the object.

6. A treatment apparatus comprising:
a holding unit having a holding surface that holds an object;
a treatment unit that executes treatment for the object held by the holding surface;
a liquid supply source that supplies the holding unit with a liquid to be ejected from the holding surface;
a removal unit that removes the liquid ejected from the holding surface; and
a controller, wherein
the controller is capable of causing the removal unit to remove the liquid in contact with both the holding surface and the object.
